(19) United States
(12) Patent Application Publication
(10) Pub. No.: US 2020/0313062 A1
(43) Pub. Date: Oct. 1, 2020

(54) THERMOELECTRIC CONVERSION ELEMENT

(71) Applicant: NEC CORPORATION, Tokyo (JP)

(72) Inventors: Yuma IWASAKI, Tokyo (JP); Masahiko ISHIDA, Tokyo (JP); Akihiro KIRIHARA, Tokyo (JP); Koichi TERASHIMA, Tokyo (JP); Ryohto SAWADA, Tokyo (JP); Hiroko SOMEYA, Tokyo (JP)

(73) Assignee: NEC CORPORATION, Tokyo (JP)

(21) Appl. No.: 16/651,914

(22) PCT Filed: Aug. 13, 2018
(86) PCT No.: PCT/JP2018/030235

§ 371 Date: Mar. 27, 2020

(30) Foreign Application Priority Data
Sep. 28, 2017 (JP) 2017-187730

(51) Int. Cl. H01L 37/04

(52) U.S. Cl. CPC H01L 37/04

(57) ABSTRACT

A thermoelectric conversion element 10 includes an anomalous Nernst material 11 having the anomalous Nernst effect, in which: the anomalous Nernst material 11 includes at least an element having the inverse spin-Hall effect; and the element is spin-polarized. By applying, for example, a magnetic field to such the thermoelectric conversion element 10 in the x direction and a temperature gradient thereto in the z direction, thermoelectromotive force can be taken out from terminals 12.

### TECHNICAL FIELD

The present invention relates to a thermoelectric conversion element that converts heat into electric power, and more particularly to a thermoelectric conversion element that uses the anomalous Nernst effect.

### BACKGROUND ART

As efforts to solve environmental and energy issues for a sustainable society are made vigorously, expectations for thermoelectric conversion elements that can convert heat into electric power rise. This is because heat is the most efficient energy source that can be obtained from various media such as body temperature, sunlight, engine, and factory exhaust heat. Thermoelectric conversion elements are expected to become more and more important in the future in order to, for example, improve efficiency of energy use in a low-carbon society and supply power to ubiquitous terminals, sensors, and the like.

Recent research has revealed that the “spin-Seebeck effect” exists in magnetic bodies (see, for example, Patent Literature 1). The spin-Seebeck effect is a phenomenon in which, when a temperature gradient is applied to a magnetic body, a spin current (flow of spin angular momentum of electrons) is generated in a direction parallel to the temperature gradient. Patent Literature 1 reports the spin-Seebeck effect in a NiFe film that is a ferromagnetic body. Non Patent Literatures 1 and 2 report the spin-Seebeck effect at an interface between a magnetic insulator and a metal film, such as yttrium iron garnet (YIG, Y₃Fe₅O₁₂).

Note that the spin current generated by the temperature gradient is converted into an electric current by the “inverse spin-Hall effect”. The inverse spin-Hall effect is a phenomenon in which a spin current is converted into an electric current by spin orbit coupling of matters. The inverse spin-Hall effect significantly appears in a substance having large spin orbit coupling (e.g., 4d element).

By using both the spin-Seebeck effect and the inverse spin-Hall effect, it is possible to convert a temperature gradient into an electric current via a spin current.

In addition to the spin-Seebeck effect, there is also known a thermoelectric effect called the anomalous Nernst effect in a conductive ferromagnetic alloy mainly made from Fe, Co, Ni, Mn, and the like (e.g., Patent Literature 2). The anomalous Nernst effect is a phenomenon in which, when a temperature difference is generated in a magnetized magnetic body in a direction perpendicular to a magnetization direction, a voltage (potential difference) is generated in an outer product direction thereof (direction perpendicular to both the magnetization direction and a heat flow direction). It is also possible to understand that a power generation effect caused by the anomalous Nernst effect is that, in a conductive magnetic material containing a substance having large spin orbit coupling, a spin current generated by a heat flow is converted into an electric current by the inverse spin-Hall effect of the substance in the same material. As disclosed in Patent Literature 2, conversion efficiency by the anomalous Nernst effect is superior to conversion efficiency by the spin-Seebeck effect at present.

The thermoelectric effect by the spin-Seebeck effect and the thermoelectric effect by the anomalous Nernst effect have such symmetry that, regarding a direction of thermoelectromotive force, electromotive force in an in-plane direction is induced by a temperature gradient in a direction perpendicular to a plane. Thus, examples of thermoelectric conversion elements using those two effects are also reported (e.g., Non Patent Literatures 3 and 4).

Hereinafter, a thermoelectric conversion element using the spin-Seebeck effect and a thermoelectric conversion element using the anomalous Nernst effect may be simply referred to as “thermoelectric conversion element”, without being distinguished in particular. The thermoelectric conversion element will also be referred to as “spin heat flow element”.

Although not for thermoelectric conversion, Patent Literature 3 discloses several examples of a magnetic metal used for a magnetic head.

### CITATION LIST

### Patent Literature

PTL 1: Japanese Patent Application Laid-Open No. 2009-130070

PTL 2: Japanese Patent Application Laid-Open No. 2014-72256

PTL 3: Japanese Patent Application Laid-Open No. 2003-242615

### Non Patent Literature

NPL 1: K. Uchida, et al., “Spin Seebeck insulator”, Nature Materials, vol.9, 2010, p. 894.

NPL 2: K. Uchida, et al., “Obserbationb of longitudinal spin-seebeck effect in magnetic insulator”, Applied Physics Letters vol.97, 2010, p. 172505.

NPL 3: B. F. Miao, S. Y. Huang, D. Qu, and C. L. Chien, “Inverse Spin Hall Effect in a Ferromagnetci Metal”, Physical Review Letters 111, 2013, p. 066602.

NPL 4: K. Uchida, et al., “Thermoelectric Generation Based on Spin Seebeck Effects”, Proceedings of the IEEE, vol. 104, No. 10, 2016, p. 1946-1973.

### SUMMARY OF INVENTION

### Technical Problem

However, at present, output of thermoelectric conversion elements is very small and has not been put into practical use. For example, FIG. 16 of Non Patent Literature 4 discloses a thermoelectric conversion element using both the spin-Seebeck effect and the anomalous Nernst effect, more specifically, normalized thermoelectric output (power factor (P.F.)) of an element including Fe₃O₄/Pt as an anomalous Nernst material on an MgO substrate. According to FIG. 16, thermoelectric conversion efficiency of the element is 0.2 pW/K² at the most. Patent Literature 3 discloses examples of a magnetic metal used for a magnetic head, but does not disclose a possibility of applying the examples to a thermoelectric conversion element. For example, Patent Literature 3 does not disclose any physical properties that are important as thermoelectric conversion elements, useful atoms, a composition ratio thereof, or the like.

The present invention has been made in view of the above problems, and an object thereof is to provide a thermoelectric conversion element that achieves high output.

### Solution to Problem

A thermoelectric conversion element according to the present invention includes an anomalous Nernst material having the anomalous Nernst effect, in which: the anomalous Nernst material includes at least an element having the inverse spin-Hall effect; and the element having the inverse spin-Hall effect is spin-polarized.

### Advantageous Effects of Invention

According to the present invention, it is possible to achieve high output of a thermoelectric conversion element.

### BRIEF DESCRIPTION OF DRAWINGS

FIG. 1 It depicts a schematic configuration diagram illustrating an example of a thermoelectric conversion element of a first exemplary embodiment.

FIG. 2 It depicts a block diagram illustrating a configuration example of a material development system used for developing an anomalous Nernst material.

FIG. 3 It depicts a block diagram illustrating a more detailed configuration example of an information processing device included in a material development system.

FIG. 4 It depicts a flowchart showing an example of operation of an information processing device in a material development system.

FIG. 5 It depicts a graph showing XRD data of FePt, CoPt, and NiPt thin films prepared in an experiment.

FIG. 6 It depicts a graph showing analysis results of a crystal structure of each composition using the XRD data of FIG. 5.

FIG. 7 It depicts an explanatory diagram showing a list of corresponding parameters of material calculation data.

FIG. 8 It depicts an explanatory diagram illustrating a neural network model used for learning and learning results thereof

FIG. 9 It depicts a graph showing calculation results of a spin polarization rate of Pt atoms of three materials.

FIG. 10 It depicts a graph showing measurement results of thermoelectric efficiency of actually prepared materials.

FIG. 11 It depicts a graph showing a relationship between a spin polarization rate of Pt atoms and the anomalous Nernst effect.

FIG. 12 It depicts an explanatory diagram schematically showing a search result of a third element (substitution type).

FIG. 13 It depicts an explanatory diagram schematically showing a search result of a third element (interstitial type).

FIG. 14 It depicts a schematic configuration diagram illustrating an example of a thermoelectric conversion element of a second exemplary embodiment.

FIG. 15 It depicts a schematic configuration diagram illustrating an example of a thermoelectric conversion element of a third exemplary embodiment.

FIG. 16 It depicts a schematic configuration diagram illustrating an example of a thermoelectric conversion element of a fourth exemplary embodiment.

FIG. 17 It depicts a configuration diagram illustrating an example of a power generation structure.

### DESCRIPTION OF EMBODIMENTS

### Exemplary Embodiment 1

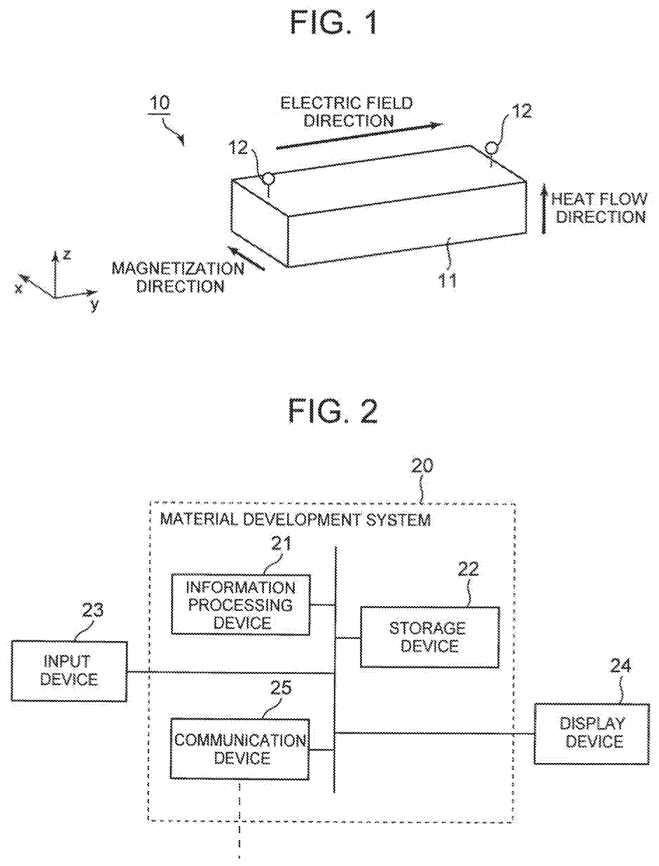

Hereinafter, exemplary embodiments of the present invention will be described with reference to the drawings. FIG. 1 depicts a schematic configuration diagram illustrating an example of a thermoelectric conversion element of a first exemplary embodiment.

As illustrated in FIG. 1, a thermoelectric conversion element 10 of this exemplary embodiment contains an anomalous Nernst material 11 that is a material having the anomalous Nernst effect. At least a pair of terminals 12 for taking out electromotive force generated in the anomalous Nernst material 11 is attached to the anomalous Nernst material 11. For example, the terminals 12 may be provided at both ends (e.g., ends in a longitudinal direction of one surface) of the anomalous Nernst material 11. The anomalous Nernst material 11 is formed as, for example, a structure (thin film or the like) having a predetermined thickness. The structure may have a shape that extends in a predetermined direction (e.g., a thin line shape).

The anomalous Nernst material 11 is, for example, a magnetic body and is a conductive material. Examples of such the anomalous Nernst material 11 encompass materials mainly made from a ferromagnetic metal or a ferromagnetic metal compound. Examples of the ferromagnetic metal encompass Fe, Co, Ni, Mn, Cr, and Gd. The anomalous Nernst material 11 is not limited to the materials mainly made from a ferromagnetic metal or a ferromagnetic metal compound, and the examples thereof may also encompass, for example, semiconductors and oxide.

In this exemplary embodiment, the anomalous Nernst material 11 is magnetized in a predetermined direction (in this example, the x direction in FIG. 1). As already described, when a heat flow is caused to flow through an anomalous Nernst material magnetized in one direction in a direction perpendicular to the magnetization direction (in this example, the z direction in FIG. 1), an electric field is generated in a direction perpendicular to both the magnetization direction and a heat flow direction (in this example, the y direction in FIG. 1). Thus, thermoelectromotive force can be taken out from the terminals 12.

The heat flow can be generated by, for example, applying a temperature gradient to two surfaces that are a start point and an end point in a desired heat flow direction (in this example, a bottom surface and a top surface obtained when an upward direction in the z direction is the top surface). A method of applying the temperature gradient is not particularly limited. However, for example, heat sources having a temperature difference may be provided to be in contact with the respective two surfaces on which the temperature gradient is to be generated.

In addition to the above condition (condition of having the anomalous Nernst effect), the anomalous Nernst material 11 of this exemplary embodiment includes an element having the inverse spin-Hall effect, and the element is spin-polarized.

Examples of the element having the inverse spin-Hall effect encompass not only 4d elements but also 5d elements and 4f elements. Herein, the 4d elements are Y, Zr, Nb, Mo, Tc, Ru, Rh, Pd, Ag, and Cd. The 5d elements are Hf, Ta, W, Pe, Os, Ir, Pt, Au, and Hg. The 4f elements are La, Ce, Pr, Nd, Sm, Eu, Gd, Tb, Dy, Hb, Er, Tm, Yb, and Lu.

It is known that the inverse spin-Hall effect is more significant as a spin hall angle is larger. It is already found that spin orbit coupling is related to one of factors that determine the magnitude of the spin hall angle. The spin orbit coupling is roughly increased in proportion to the atomic number. Thus, in addition to the above elements, elements having electrons in the 4d or more orbital, such as Ti, Pb, and Bi, i.e., elements having the atomic number of 39(Y) or more are expected to have large spin orbit coupling. Therefore, those elements are preferable as the element included in the anomalous Nernst material 11.

Hereinafter, in the anomalous Nernst material 11, an element mainly having ferromagnetism may be referred to as “first element”, and an element having the inverse spin-Hall effect may be referred to as “second element”. Note that the above expressions are classified according to properties, and the expressions do not deny that the first element is the second element.

Generally, an element significantly having the inverse spin-Hall effect (corresponding to the second element) is not spin-polarized by itself. Thus, in this exemplary embodiment, the element significantly having the inverse spin-Hall effect is spin-polarized by combining the element significantly having the inverse spin-Hall effect and another element. Hereinafter, the element that is combined with the element significantly having the inverse spin-Hall effect to spin-polarize the element significantly having the inverse spin-Hall effect or that improves a spin polarization rate of the element may be referred to as “third element”.

Therefore, the anomalous Nernst material 11 of this exemplary embodiment is a magnetic body and is a conductive material, and is preferably a material including at least an element (second element) significantly having the inverse spin-Hall effect and an element (third element) that spin-polarizes the element or improves a spin polarization rate of the second element. The anomalous Nernst material 11 may be, for example, a multi-element system including three or more elements, and may be a material including at least the first element belonging to a magnetic metal, the second element having the inverse spin-Hall effect, and the third element that spin-polarizes the second element or improves the spin polarization rate of the second element.

As an example, the anomalous Nernst material 11 may be an alloy including at least one of Co, Fe, Ni, Mn, Cr, or Gd as the first element, at least one of the 4d elements, the 5d elements, or the 4f elements as the second element, and at least one of elements described below as the third element. A combination of the first element, the second element, and the third element is not limited to this example, and any combination may be used as long as each combination has the characteristics described above and finally has the anomalous Nernst effect.

In particular, the third element is not particularly limited as long as the third element can spin-polarize the second element having the inverse spin-Hall effect or improve the spin polarization rate of the second element.

Relevance of strength of the spin polarization rate of the element having the inverse spin-Hall effect to strength of the anomalous Nernst effect caused by the material (power generation efficiency), which is one of characteristics of the anomalous Nernst material 11 of this exemplary embodiment, has been first found by a material development system newly developed by the inventors of the present invention.

Hereinafter, an overview of the material development system that has found this finding will be described.

FIG. 2 depicts a block diagram illustrating a configuration example of the material development system used for developing the anomalous Nernst material 11 of this exemplary embodiment. This material development system 20 is a system that analyzes a relationship between physical properties and effects (power generation efficiency) of materials by machine learning using big data regarding materials. The meaning of machine learning is interpreted as including, for example, artificial intelligence (AI) in a broad sense. A method of developing materials by using machine learning (AI) as described above is called materials informatics.

As illustrated in FIG. 2, the material development system 20 includes an information processing device 21, a storage device 22, an input device 23, a display device 24, and a communication device 25 that communicates with external devices. Those devices are connected to each other.

The storage device 22 is, for example, a storage medium such as a nonvolatile memory and stores various data used in the material development system 20.

For example, the storage device 22 stores the following data.
Programs for processing operation performed by the information processing device 21 and the like
Machine learning programs
Calculation programs of first-principle calculation, molecular kinetics, and the like
Experimental data regarding various materials obtained by a combinatorial method or the like (material experimental data)
Calculation data regarding various materials obtained by the first-principle calculation, the molecular kinetics, and the like (material calculation data)
Machine learning results (material analysis data)

Herein, the material experimental data is data regarding materials and is obtained by experiments on the materials. The material calculation data is data regarding the materials and is obtained by calculation. The material experimental data only needs to be, for example, data regarding characteristics, structures, and compositions of actual materials observed or measured as a result of experiments on the actual materials. The material calculation data only needs to be, for example, data regarding characteristics of virtual materials calculated according to a predetermined principle.

The data regarding the materials may be calculated by the material development system 20 or may be data described in an existing material database or a publicly known paper. In the latter case, the material development system 20 may access an external material database via the communication device 25 to obtain desired data. A format of the data may be a numeric format such as a scalar, vector, or tensor, or may be a still image, a moving image, a character string, a sentence, or the like.

Further, the material development system 20 may obtain the data regarding the materials by accessing an experimental device or the like via the communication device 25 and controlling the accessed device.

The input device 23 is an input device such as a mouse or a keyboard, and accepts an instruction from a user. The display device 24 is an output device such as a display and displays information obtained by this system.

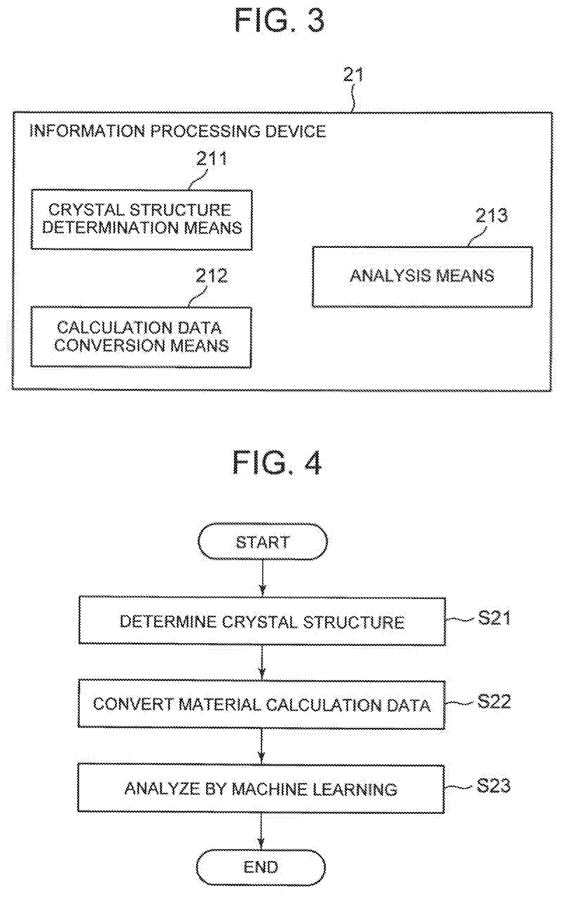

FIG. 3 depicts a block diagram illustrating a more detailed configuration example of the information processing device 21 included in the material development system 20. As illustrated in FIG. 3, the information processing device 21 may include crystal structure determination means 211, calculation data conversion means 212, and analysis means 213.

The crystal structure determination means 211 determines a crystal structure (ratio, in particular) of a target material in specified data on the basis of crystal structure information such as X-ray diffraction (XRD) data.

Based on the crystal structure determined by the crystal structure determination means 211, the calculation data conversion means 212 converts (corrects or reconstructs) the material calculation data regarding the target material so as to reduce a gap between the material calculation data and the material experimental data.

The analysis means 213 performs analysis by machine learning by using a material calculation data group including the material calculation data converted by the calculation data conversion means 212 and a material experimental data group.

FIG. 4 depicts a flowchart showing an example of operation of the information processing device 21 in the material development system 20. In the example illustrated in FIG. 4, first, the crystal structure determination means 211 determines a crystal structure (the type of long-range order and a ratio thereof) of each material that is a target material of the material experimental data (step S21). As described above, the crystal structure determination means 211 may obtain the crystal structure by fitting the XRD data with an arbitrary curve and determining a ratio of each structure peak area and peak height, or may obtain the crystal structure from unsupervised learning such as hard clustering or soft clustering.

Next, the calculation data conversion means 212 converts the material calculation data on the basis of the crystal structure obtained in step S21 (step S22).

Now, a crystal structure of a target material “M1” in the material experimental data includes a face centered cubic lattice (fcc), a body centered cubic lattice (bcc), and a hexagonal close packed lattice (hcp), and a ratio of those lattices is determined to be A_{fcc}, A_{bcc}, and A_{hcp}, Note that A_{fcc}+A_{bcc}+A_{hcp}=1 is satisfied. The material calculation data is calculated on the assumption of a single crystal structure. Further, there is material calculation data indicating values of magnetic moments obtained by the first-principle calculation according to the respective types as data of the single crystal structure of the target material “M1”, and those values are M_{fcc}, M_{bcc}, and M_{hcp}.

In such a case, the calculation data conversion means 212 reconstructs the material calculation data so as to reduce a gap caused by a difference in crystal structure between the material calculation data and the material experimental data of the same composition. In this example, the calculation data conversion means 212 performs the following conversion in order to bring a value of a certain characteristic of the material calculation data acquired on the condition of a single crystal structure close to a value of the characteristic in the crystal structure of the material experimental data. Specifically, the calculation data conversion means 212 adds the material calculation data of the single crystal structures corresponding to the crystal lattices included in the crystal structure of the material experimental data by using the ratio as a weight, thereby generating (reconstructing) new material calculation data indicating a characteristic value corresponding to a crystal structure of a complex. In the above case, a magnetic moment Mc after reconstruction is expressed by, for example, the following equation.

Mc=A_{fcc}M_{fcc}+A_{bcc}M_{bcc}+A_{hcp}M_{hcp} (1)

However, the above method is merely an example, and a conversion processing (data adaptation processing) method by the calculation data conversion means 212 is not limited thereto.

Next, the analysis means 213 performs machine learning by using the material calculation data and the material experimental data, and analyzes a relationship between parameters of each data (step S23). At this time, the analysis means 213 uses the converted material calculation data in step S23, instead of the material calculation data used as a conversion source. There are various machine learning methods such as supervised learning, unsupervised learning, semi-supervised learning, and reinforcement learning, and the machine learning method is not particularly limited in this exemplary embodiment.

By using the material development system 20, it is possible to perform machine learning after reducing a gap between the material experimental data regarding materials of compounds, complexes, and the like that cannot be easily obtained by calculation and the material calculation data obtained on the assumption of a relatively simple configuration in terms of a composition, a crystal structure, a shape, and the like. This makes it possible to obtain a more appropriate learning result. Therefore, for example, by analyzing a huge amount of data by using this system, it is possible to, for example, obtain new information such as a relationship between parameters of materials that cannot be noticed by human beings. Thus, it is possible to obtain information useful for developing a more functional material.

In the above example, the material calculation data is converted by analyzing the crystal structure of the target material of the material experimental data. However, a target to be analyzed is not limited to the crystal structure. The target to be analyzed may be, for example, composition (type and ratio of raw materials including additives and the like), shapes (conditions such as thickness and width), and ambient environment conditions (e.g., temperature, magnetic field, pressure, and vacuum conditions). Further, there has been described an example where the material calculation data of a target material is reconstructed on the basis of the material calculation data of the same material as the target material of the material experimental data. However, for example, it is also possible to reconstruct the material calculation data of a target material that is the same material as the target material of the material experimental data by using material data (either calculation data or experimental data) having partially different raw materials such as additives.

As already described, in the present invention, the above material development system 20 is used for developing an anomalous Nernst material. As a result, regarding the anomalous Nernst material, the above relevance that cannot be explained by current physics is founded. More specifically, it is found that “there is a positive correlation between the spin polarization of Pt atoms and thermoelectric conversion efficiency caused by the anomalous Nernst effect”.

Hereinafter, a method of using the material development system 20 to develop the anomalous Nernst material will be described more specifically.

First, regarding three alloy thin films having compositions of Pe₁₋ₓPtₓ, Co₁₋ₓPtₓ, and Ni₁₋ₓPtₓ created on Si substrates, XRD data of each composition, conversion efficiency data of each composition caused by the anomalous Nernst effect, and each data obtained by the first-principle calculation of each composition were stored in the storage device 22. Herein, x represents a content ratio of platinum Pt, and is an arbitrary number of 0 or more but less than 1.

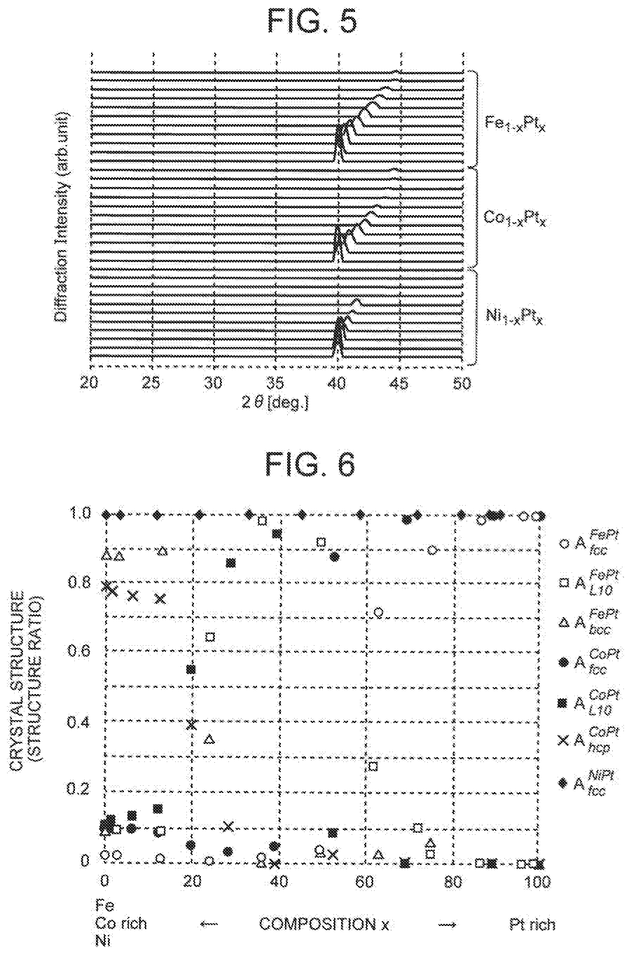

FIG. 5 shows XRD data of each composition. In step S21, the crystal structure was determined on the basis of this XRD data. Herein, non-negative matrix factorization (NMF), which is one of unsupervised learning, was used. By analyzing each XRD data with NMF, it was found that Fe₁₋ₓPtₓ, Co₁₋ₓPtₓ, and Ni₁₋ₓPtₓ were each divided into three structures, and the types of the structures (crystal structure) are four in total (fcc, bcc, hcp, and L1₀). FIG. 6 depicts a graph showing analysis results of the crystal structures of each composition using the XRD data. Such analysis results show that, for example, a material of Co_{0.81}Pt_{0.19} prepared in the experiment is a material having, as the crystal structures, about 55% of the Llo structure, about 40% of the hcp structure, and about 5% of the fcc structure.

Next, in step S22, the material calculation data of each composition was converted on the basis of structure ratio data indicating the type and ratio of the structures in the crystal structure of each composition thus obtained.

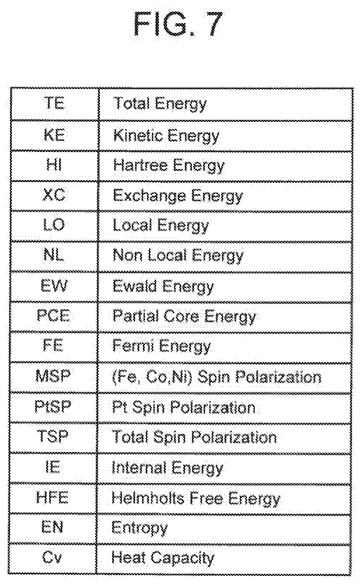

FIG. 7 shows a list of the corresponding parameters of the material calculation data and abbreviations thereof. All the material calculation data herein was obtained by the first-principle calculation. Each item (corresponding parameter) was calculated for each of the structures (fcc, bcc, hcp, L1₀) forming the crystal structure of each composition.

The material calculation data of each structure of each composition was substituted into Equation (1) to reconstruct the material calculation data of a complex of the compositions. For example, it is found from FIG. 6 that the structural ratio of Co_{0.81}Pt_{0.19} that is the target material of the material experimental data is 5%, 0%, 40%, and 55% for fcc, bcc, hcp, and L10, respectively. Further, values of the material calculation data in the structures of Co_{0.81}Pt_{0.19} indicating total energy (TE) included in the material calculation data group are represented by TE_{fcc}, TE_{bcc}, TE_{L10}, and TE_{hcp}. In that case, total energy TE_{C}, which is a value of the reconstructed material calculation data (material calculation data of the complex having the same composition as that of the complex in the material experimental data), was calculated as in Equation (2).

TE_{C}=0.05*TE_{fcc}+0*TE_{bcc}+0.4*TE_{hcp}+0.55*TE_{L10} (2)

Other data obtained from the first-principle calculation was also similarly converted.

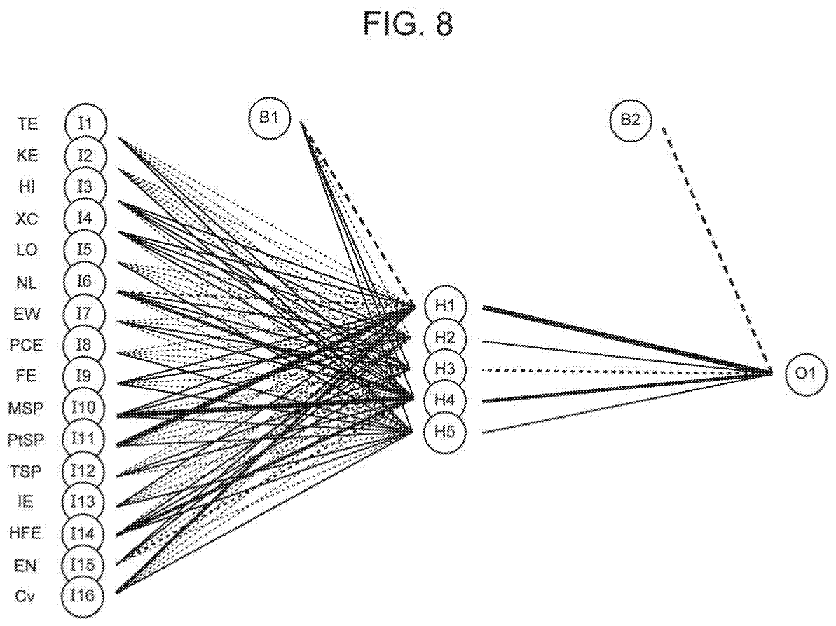

Next, in step S23, the reconstructed material calculation data thus obtained and the material experimental data (conversion efficiency data caused by the anomalous Nernst effect obtained in the experiment) were analyzed by machine learning. Herein, regression using a neural network, which is one of the simple supervised learning, was performed. Herein, as illustrated in FIG. 8, the neural network was trained by setting the material calculation data in an input unit and setting the material experimental data in an output unit.

FIG. 8 illustrates visualization of the trained neural network model. In FIG. 8, each circle represents a node. Nodes “I1” to “I11” represent respective input units. Nodes “H1” to “H5” represent hidden units. Nodes “B1” to “B2” represent bias units. A node “O1” represents an output unit. Each path connecting the nodes represents connection of the nodes. Each of those nodes and a connection relationship therebetween simulate firing of brain neurons. A thickness of a line of the path corresponds to strength of the connection, and a line type thereof corresponds to a sign of the connection (the solid line indicates positive and the broken line indicates negative).

Strength of the relationship can be found from the strength of the path from the corresponding parameter (input parameter) of each material calculation data to the thermoelectric conversion efficiency (output parameter) caused by the anomalous Nernst effect in learning results illustrated in FIG. 8. That is, the strongest path among those paths is connected from the node “I11” to the node “O1” via the node “H1”, and the sign thereof is positive (solid line). This indicates that there is a strong positive correlation between spin polarization of Pt atoms (PtSP) and thermoelectric conversion efficiency caused by the anomalous Nernst effect.

As already described, a hypothesis that “there is a positive correlation between the spin polarization of Pt atoms and the thermoelectric conversion efficiency caused by the anomalous Nernst effect” cannot be explained by current condensed matter physics. However, according to this correlation obtained from the learning results of this system, it is expected that, if the spin polarization of Pt atoms in a material is increased, an anomalous Nernst material having a more efficient power generation effect can be obtained.

In view of this, the present inventors actually developed an anomalous Nernst material on the basis of this knowledge thus obtained, and, as a result, obtained an anomalous Nernst material 11 having high thermoelectric conversion efficiency. As an example, the anomalous Nernst material 11 having the thermoelectric conversion efficiency of 4.0 pW/K² on a Si substrate was obtained (see Example 1 described later).

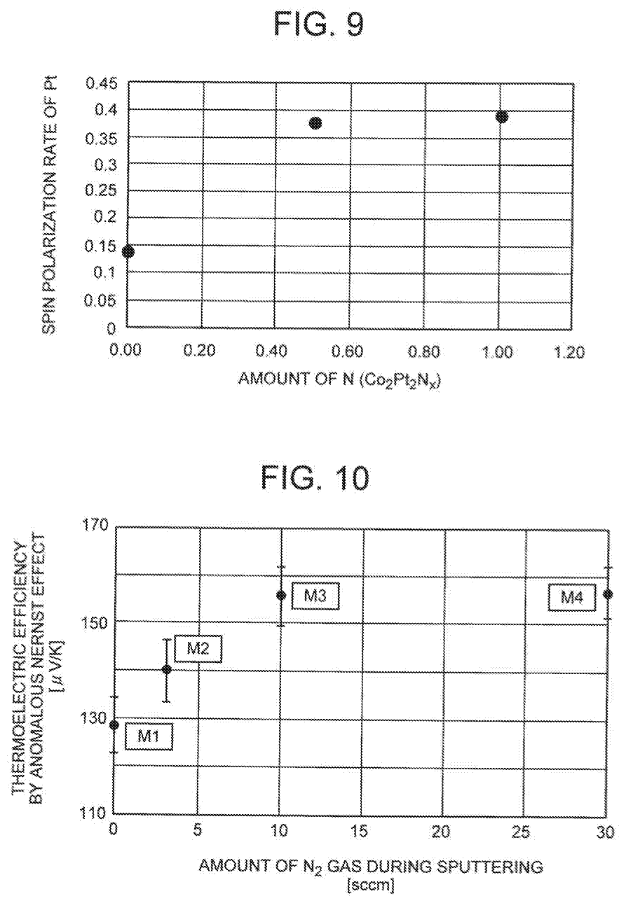

FIG. 9 depicts a graph showing calculation results of the spin polarization rate of Pt atoms of three materials. Specifically, the three materials are Co₂Pt₂, Co₂Pt₂N_{0.5}, and Co₂Pt₂N₁. Equation (3) below was used as a calculation equation for the spin polarization rate of Pt atoms.

$$\begin{matrix}[ Mathematical Formula 1 ] & \\ {P}_{P t} = \frac{{D}_{P t}^{↑} - {D}_{P t}^{↓}}{{D}_{P t}^{↑} + {D}_{P t}^{↓}} & ( 3 )\end{matrix}$$

In Equation (3), P represents the spin polarization rate. A lower right symbol of P represents a target material or element. Therefore, P_{Pt} represents the spin polarization rate of Pt. D represents state density. A lower right symbol of D represents a target material or element, and an upper right symbol (up or down arrow) represents up spin or down spin on the Fermi surface. The up arrow represents the up spin. Therefore, D_{Pt}^{↑} represents state density of the up spin of Pt atoms on the Fermi surface, and D_{Pt}^{↓} represents state density of the down spin of Pt atoms on the Fermi surface.

The state density may be derived by, for example, the first-principle calculation. In the example of FIG. 9, a method using a pseudopotential method and a plane wave basis (specifically, PHASE software) was used to calculate the state density. In addition to the above method, for example, a method using a Green's function method and a coherent potential (e.g., AkaiKKR software) may be used.

Among the above materials, a material containing nitrogen N was calculated as an interstitial alloy in which nitrogen N, which is the third element, entered a gap (more specifically, the center of the fcc structure) between atoms in a crystal structure of a Co₂Pt₂ alloy. Depending on the combination of elements, the material may be a substitutional alloy in which the third element is substituted at a position of an atom in a crystal structure of the alloy of the first element and the second element. In such a case, the spin polarization rate only needs to be calculated on the basis of the state density of the second element in the substitutional alloy.

As illustrated in FIG. 9, the spin polarization rate of Pt atoms in Co₂Pt₂ containing no nitrogen N is about 0.144, whereas the spin polarization rates thereof in Co₂Pt₂N_{0.5} and Co2Pt2N1 containing nitrogen N are 0.378 and 0.392, respectively. From those calculation results, it is found that the more N is contained in the alloy of Co and Pt, the higher the spin polarization rate of Pt becomes.

FIG. 10 depicts a graph showing measurement results of thermoelectromotive force caused by the anomalous Nernst effect of the thermoelectric conversion elements made from four actually prepared materials. The four materials are materials Coₙ₁Ptₙ₂N₁₋ₙ₁₋ₙ₂ (where 0<n1<1, 0<n2<1, 0<n1+n2<1) obtained by adding N to the alloy of Co and Pt while changing an amount of N. More specifically, the four materials are M1: Co_{0.479}Pt_{0.493}N_{0.028}, M2: Co_{0.455}Pt_{0.485}N_{0.060}, M3: Co_{0.456}Pt_{0.477}N_{0.067}, and M4: Co_{0.449}Pt_{0.470}N_{0.081}. Herein, Co corresponds to the first element, Pt corresponds to the second element, and N corresponds to the third element. Those materials were prepared by changing only a flow rate of a N2 gas during sputtering, without changing sputtering power of Co and Pt from 1 : 1. A composition ratio of the above CoPtN was obtained by XPS measurement.

It is found, from FIG. 10, that the larger the amount of N in CoPtN is, the larger thermoelectromotive force caused by the anomalous Nernst effect becomes. Those values are values of electromotive force obtained from samples in examples described below. Specifically, M1, M2, M3, and M4 have 128.5 μV/K, 139.9 μV/K, and 155.6 μV/K, and 156.6 μV/K, respectively. Values obtained by normalizing those values by 1 mm×1 mm are 21.4 μV/K, 23.3 μV/K, 25.9 μV/K, and 26.1 μV/K, respectively. However, the values in FIG. 10 are values of electromotive force obtained when a temperature gradient of 1 K is applied between the top and bottom of a sample including a Si substrate as described below. Note that, although the flow rate of N₂ gas in M1 was set to 0, it is considered that M1 contains a small amount of N as a result of reaction between a sample and N in the air during movement of the sample from the sputtering device to the XPS device.

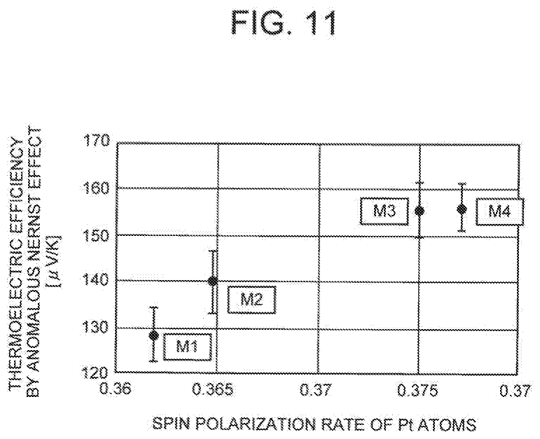

Therefore, the spin polarization rate of Pt atoms in each material was calculated on the basis of the composition ratio of the four materials obtained by XPS. The resultant spin polarization rates of Pt atoms in M1, M2, M3, and M4 are 0.361, 0.364, 0.375, and 0.377, respectively. Those values were calculated by the first-principle calculation (AkaiKKR software) using a coherent potential. FIG. 11 depicts a graph showing a relationship between the calculation results of the spin polarization rate of Pt atoms in each material and thermoelectromotive force obtained by the experiment. According to FIG. 11, it is found that the larger the amount of N in CoPtN is and the higher the spin polarization rate of Pt atoms in CoPtN is, the larger thermoelectromotive force caused by the anomalous Nernst effect becomes.

Based on the results of FIGS. 9 to 11, the following can be said. For example, in a case where the spin polarization rate of Pt atoms is 0.145 or more, an effect of increasing the spin polarization rate of the second element, which is caused by including the third element in the anomalous Nernst material 11, is recognized. The spin polarization rate of Pt atoms is more preferably 0.36 or more, and further preferably 0.37 or more. Further, by combining the results of FIGS. 9 and 11, in a case where a voltage obtained when a sample size is normalized to 1 mm×1 mm (hereinafter, referred to as “normalized voltage”) is 21 μV/K or more, it can be said that an effect of increasing the thermoelectric conversion efficiency caused by the increase in the spin polarization rate of the second element in the anomalous Nernst material 11 is obtained as the thermoelectric conversion efficiency based on the anomalous Nernst effect of the thermoelectric conversion element 10. The normalized voltage obtained by the thermoelectric conversion element 10 of this exemplary embodiment is more preferably 23 μV/K or more, and further preferably 25 μV/K or more. However, when the voltage is evaluated, an influence by a difference in measurement conditions (e.g., the thermal conductivity, electrical conductivity, and the like of the substrate used in the sample) is considered.

Further, from the results of FIG. 10 and the measurement results of XPS, the proportion of the third element in the anomalous Nernst material 11, more specifically, the proportion of atoms corresponding to the third element to the total number of atoms in the anomalous Nernst material 11 (corresponding to 1-n1-n2 in the above Coₙ₁Ptₙ₂N₁₋ₙ₁₋ₙ₂) is preferably equal to or more than 0.02. This is because the effect caused by the increase in the spin polarization rate of the second element, which is caused by including the third element in the anomalous Nernst material 11, is obtained. The composition ratio of the third element in the anomalous Nernst material 11 is preferably 0.02 or more, more preferably 0.06 or more, and further preferably 0.065 or more. Further, an amount of increase in the thermoelectric conversion efficiency (voltage) with respect to a change in N content in M3 and M4 is not so large. Therefore, the composition ratio of the third element in the anomalous Nernst material 11 may be 0.1 or less or 0.08 or less.

The analysis results by the material development system 20 show a strong correlation between the spin polarization rate of Pt atoms and the thermoelectric conversion efficiency.

This is because the material experimental data that can be prepared is limited to data regarding materials containing Pt as the second element due to difficulty of experiments regarding the anomalous Nernst effect. Considering a physical principle of the anomalous Nernst effect, it is considered that not only Pt but also other elements (second element) significantly having the inverse spin-Hall effect have the similar relationship. That is, it is considered that “there is a positive correlation between the spin polarization of the element (second element) significantly having the inverse spin-Hall effect and the thermoelectric conversion efficiency caused by the anomalous Nernst effect”.

As described above, it is considered that the stronger the spin polarization of the second element included in the anomalous Nernst material 11 is, the higher the thermoelectric conversion efficiency becomes. Therefore, stronger spin polarization of the second element included in the anomalous Nernst material 11 is preferable.

For example, according to FIG. 9, the spin polarization rate of Pt in the material in which N is inserted in the alloy of Co and Pt shows a value more than 0.144 obtained when N is not contained. Therefore, the spin polarization rate of the second element of the anomalous Nernst material 11 only needs to be higher than that of the same type of material including no third element. For example, the spin polarization rate of the second element in the anomalous Nernst material 11 is preferably 0.15 or more, more preferably 0.36 or more, and further preferably 0.37 or more.

Herein, regarding the anomalous Nernst material, the same type of material including no third element is a material made from a raw material obtained by excluding the third element from a raw material of the anomalous Nernst material 11. In the above example, the same type of material including no third element corresponds to CoPt in a case of CoPtN.

Further, the composition ratio of the second element to the first element in the anomalous Nernst material 11, i.e., a ratio N1/N2 of the normalized number of atoms N1 of the first element to the normalized number of atoms N2 of the second element in the material is more preferably 0.7 or more but 1.3 or less. Herein, the normalized numbers of atoms N1 and N2 are the numbers of atoms of the first element and the second element in αₙ₁βₙ₂γ₁₋ₙ₁₋ₙ₂, where α represents an atom corresponding to the first element, 13 represents an atom corresponding to the second element, γ represents an atom corresponding to the third element, and a composition thereof is represented by αₙ₁βₙ₂γ₁₋ₙ₁₋ₙ₂ (where 0<n1<1, 0<n2<1, 0<n1+n2<1).

This is because, in a case where the composition ratio N1/N2 is less than 0.7, magnetism of the anomalous Nernst material is weakened due to the small number of atoms of the first element, thereby reducing the thermoelectric conversion efficiency. This is also because, in a case where the composition ratio N1/N2 is higher than 1.3, an action of converting a spin current into an electric current in the anomalous Nernst material is weakened due to the small number of atoms of the second element having the spin orbit coupling, thereby reducing the thermoelectric conversion efficiency.

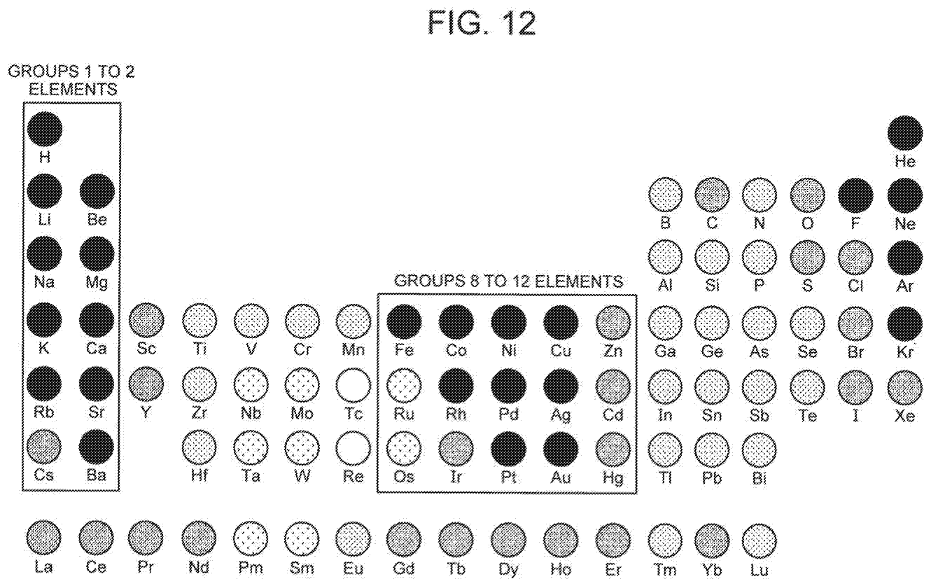

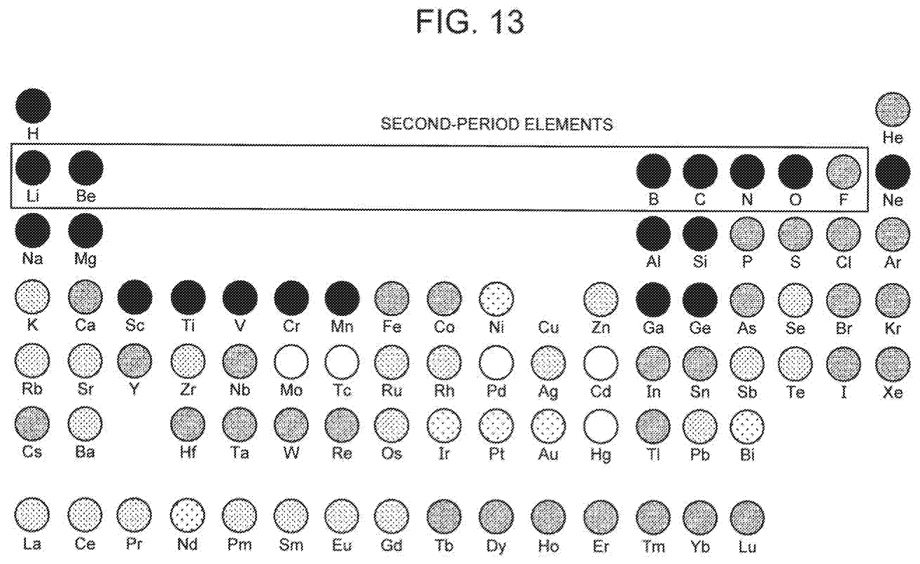

As already described, the third element is not particularly limited as long as the third element is an element that improves the spin polarization rate of the element (second element) having the inverse spin-Hall effect, such as Pt atoms. However, as rough indication, FIGS. 12 and 13 shows search results for the third element. FIGS. 12 and 13 schematically show calculation results of the spin polarization rate of Pt atoms in materials obtained by adding various elements as the third element (part corresponding to X) to the anomalous Nernst material 11 (CoPtX) containing Co as the first element and Pt as the second element. In FIGS. 12 and 13, each circle placed at the corresponding position in the periodic table and each element symbol below the circle indicate an element that is a candidate for the third element. Darker shading (actually, coloring) of the circle indicates a higher calculation result of the spin polarization rate of Pt atoms in CoPtX including the element. Equation (3) above is used to calculate the spin polarization rate of Pt atoms. FIG. 12 shows the calculation result obtained in a case where the candidate for the third element is inserted in the substitution type, and FIG. 13 shows the calculation result obtained in a case where the candidate for the third element is inserted in the interstitial type.

According to FIG. 12, in a case where the third element is inserted as a substitutional alloy with respect to the compound of the first element and the second element, groups 1 to 2 elements (H, Li, Na, K, Rb, Cs, Be, Mg, Ca, Sr, and Ba) and groups 8 to 12 elements (Fe, Ru, Os, Co, Rh, Ir, Pd, Pt, Cu, Ag, Au, Zn, Cd, and Hg) are relatively preferable as the third element. Further, according to FIG. 13, in a case where the third element is inserted as an interstitial alloy with respect to the compound of the first element and the second element, second-period elements (Li, Be, B, C, N, O, and F) are relatively preferable as the third element. Elements in and after the third period are excluded from targets of interstitial-type quality determination because those elements are likely to be inserted as the substitutional alloy instead of the interstitial alloy due to the size of atoms. In addition, inert gases are also excluded from the targets of the quality determination. Note that, even in a case where the first element is other than Co or the second element is other than Pt, the similar elements are considered promising as the third element.

Next, a method of manufacturing the thermoelectric conversion element 10 of this exemplary embodiment will be described with reference to FIG. 1. First, the anomalous Nernst material 11 is prepared. Examples of the method encompass a method in which synthetic powder generated by atomizing, physical vapor deposition (PVD), chemical vapor deposition (CVD), ion reaction, drying, or the like is baked to form a polycrystal. A method of making each material amorphous (amorphous alloy) by melting the material and thereafter rapidly freezing the material may also be used. Alternatively, a method of obtaining a single crystal from a solute obtained by synthesizing the raw materials by a gas phase method, a liquid phase method, a solid phase method, or the like may also be used. Next, at least the pair of terminals 12 is attached to the generated anomalous Nernst material 11.

When a direction (desired electric field direction) in which the terminals 12 of the thermoelectric conversion element 10 thus obtained are arranged is the y direction in FIG. 1, thermoelectromotive force can be taken out from the terminals 12 by applying a magnetic field to the thermoelectric conversion element 10 in the x direction and a temperature gradient thereto in the z direction. Note that the above manufacturing method is merely an example, and is not limited thereto.

As described above, according to this exemplary embodiment, it is possible to further increase output of the thermoelectric conversion element.

Note that a structure and the like for taking out the thermoelectromotive force from the anomalous Nernst material 11 (a shape of the anomalous Nernst material 11, attachment positions of the terminals, and the like) are not limited to the example of FIG. 1. For example, the thermoelectric conversion element 10 may have a configuration in which a plurality of thin wires made from the anomalous Nernst material 11 and magnetized in a predetermined direction is electrically connected in series as disclosed in Patent Literature 2.

### Exemplary Embodiment 2

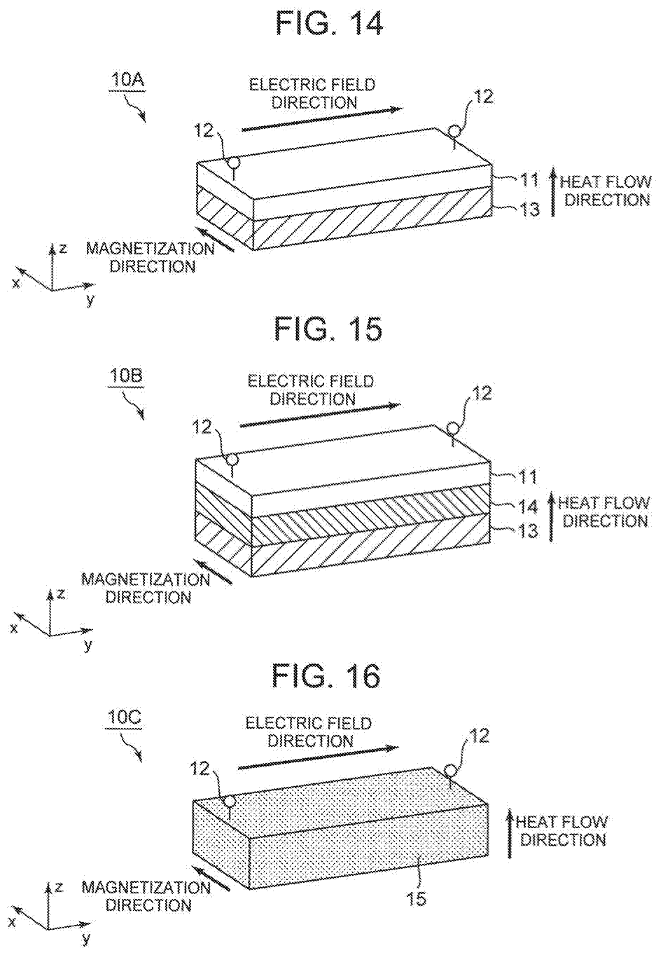

Next, a second exemplary embodiment of the present invention will be described. FIG. 14 depicts a schematic configuration diagram illustrating an example of a thermoelectric conversion element 10A of this exemplary embodiment. As illustrated in FIG. 14, the thermoelectric conversion element 10A of this exemplary embodiment is different from the thermoelectric conversion element 10 of the first exemplary embodiment in that the thermoelectric conversion element 10A further includes a substrate 13.

That is, in the thermoelectric conversion element 10A of this exemplary embodiment, an anomalous Nernst material 11 is formed on the substrate 13, and at least a pair of terminals 12 is provided on the anomalous Nernst material 11 on the substrate 13.

A material of the substrate 13 is not particularly limited. However, considering the thermoelectric conversion efficiency, a temperature gradient applied to the substrate 13 does not affect the thermoelectric effect, and thus, thermal conductivity of the substrate 13 is preferably as high as possible. Examples of the material of the substrate 13 encompass Si and SiC.

Other points are the same as in the first exemplary embodiment.

Next, a method of manufacturing the thermoelectric conversion element 10A of this exemplary embodiment will be described with reference to FIG. 14. In this exemplary embodiment, a film made from the anomalous Nernst material 11 (anomalous Nernst material layer) is formed on the substrate 13. Examples of the method encompass sputtering, vapor deposition, plating, and screen printing. Next, at least the pair of terminals 12 is attached to the anomalous Nernst material layer formed on the substrate 13.

When a direction (desired electric field direction) in which the terminals 12 of the thermoelectric conversion element 10A thus obtained are arranged is the y direction in FIG. 14, thermoelectromotive force can be taken out from the terminals 12 by applying a magnetic field to the thermoelectric conversion element 10A in the x direction and a temperature gradient thereto in the z direction. Note that the above manufacturing method is merely an example, and is not limited thereto.

As described above, according to this exemplary embodiment, a thermoelectric conversion element having high thermoelectric conversion efficiency can be obtained as in the first exemplary embodiment.

### Exemplary Embodiment 3

Next, a third exemplary embodiment of the present invention will be described. FIG. 15 depicts a schematic configuration diagram illustrating an example of a thermoelectric conversion element 10B of this exemplary embodiment. As illustrated in FIG. 15, the thermoelectric conversion element 10B of this exemplary embodiment includes a spin-Seebeck material 14 on a substrate 13, and includes an anomalous Nernst material 11 thereon. At least a pair of terminals 12 is provided on the anomalous Nernst material 11. For example, the terminals 12 may be provided at both ends (e.g., ends in a longitudinal direction of one surface) of the anomalous Nernst material 11. The anomalous Nernst material 11 and the spin-Seebeck material 14 are formed as, for example, a structure (thin film or the like) having a predetermined thickness. The structure may have a shape that extends in a predetermined direction (e.g., a thin line shape).

The spin-Seebeck material 14 is not particularly limited as long as the spin-Seebeck material 14 is a material having the spin-Seebeck effect, such as a magnetic material. The spin-Seebeck material 14 can be, for example, an oxide magnetic material such as yttrium iron garnet (YIG, Y₃Fe₅O₁₂), yttrium iron garnet doped with rare earth elements including Bi (Bi:YIG, BiY₂Fe₅O₁₂, or the like), Co ferrite (CoFe₂O₄), or magnetite (Fe₃O₄).

In this exemplary embodiment, both the anomalous Nernst material 11 and the spin-Seebeck material 14 are magnetized in a predetermined direction (e.g., the x direction in FIG. 15) in an in-plane direction.

When a heat flow is caused to flow through such the thermoelectric conversion element 10B in a direction perpendicular to the magnetization direction (e.g., the z direction in FIG. 15), a spin current is generated in a direction of the heat flow in the spin-Seebeck material 14. The spin current enters the anomalous Nernst material 11, and a first electric field is generated in the in-plane direction (the y direction in FIG. 15) of the anomalous Nernst material 11 by the inverse spin-Hall effect of the anomalous Nernst material 11. In this exemplary embodiment, in addition to the first electric field, a second electric field is also generated in the same direction as that of the first electric field (an outer product direction of the magnetization direction and the heat flow direction) in the anomalous Nernst material 11 by the anomalous Nernst effect of the anomalous Nernst material 11. As a result, thermoelectromotive force obtained by adding the first electric field and the second electric field can be taken out from the terminals 12 attached to both the ends of the anomalous Nernst material 11.

Other points are the same as in the first and second exemplary embodiments.

Next, a method of manufacturing the thermoelectric conversion element 10B of this exemplary embodiment will be described with reference to FIG. 15. In this exemplary embodiment, a film made from the spin-Seebeck material 14 (spin-Seebeck material layer) is formed on the substrate 13. Examples of a method thereof encompass metal organic deposition (MOD), pulsed laser deposition (PLD), liquid phase epitaxy (LPE), plating, and sputtering. Next, a film made from the anomalous Nernst material 11 (anomalous Nernst material layer) is formed on the formed spin-Seebeck material layer. Examples of the method encompass sputtering, vapor deposition, plating, and screen printing. Next, at least the pair of terminals 12 is attached to the formed anomalous Nernst material layer.

When a direction (desired electric field direction) in which the terminals 12 of the thermoelectric conversion element 10B thus obtained are arranged is the y direction in FIG. 15, thermoelectromotive force can be taken out from the terminals 12 by applying a magnetic field to the thermoelectric conversion element 10B in the x direction and a temperature gradient thereto in the z direction. Note that the above manufacturing method is merely an example, and is not limited thereto.

As described above, according to this exemplary embodiment, not only electromotive force caused by the anomalous Nernst effect but also electromotive force caused by the spin-Seebeck effect can be taken out. Thus, it is possible to achieve a more efficient thermoelectric conversion element.

### Exemplary Embodiment 4

Next, a fourth exemplary embodiment of the present invention will be described. FIG. 16 depicts a schematic configuration diagram illustrating an example of a thermoelectric conversion element 10C of this exemplary embodiment. As illustrated in FIG. 16, the thermoelectric conversion element 10C of this exemplary embodiment includes, on a substrate 13, a power generation structure 15 that is a hybrid structure of an anomalous Nernst material and a spin-Seebeck material. At least a pair of terminals 12 is provided on the power generation structure 15. For example, the terminals 12 may be provided at both ends (e.g., ends in a longitudinal direction of one surface) of the power generation structure 15. The power generation structure 15 (hybrid structure of the anomalous Nernst material and the spin-Seebeck material) is formed as, for example, a structure (thin film or the like) having a predetermined thickness. The power generation structure 15 may have a shape that extends in a predetermined direction. Further, the thermoelectric conversion element 10C may further include a substrate 13 as in the second exemplary embodiment.

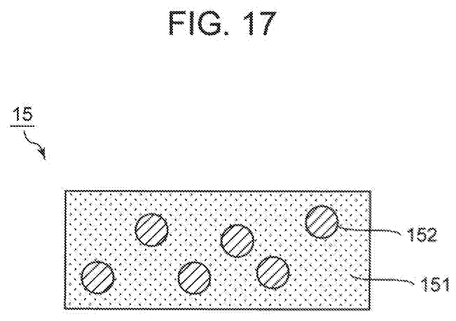

FIG. 17 illustrates an example of the power generation structure 15. The power generation structure 15 is a structure in which an anomalous Nernst material 151 and a spin-Seebeck material 152 are mixed. For example, as illustrated in FIG. 17, the power generation structure 15 has a structure in which the spin-Seebeck material 152 is embedded in the anomalous Nernst material 151. The power generation structure 15 may be, for example, a structure in which fine particles of the spin-Seebeck material 152 coated with the anomalous Nernst material 151 are aggregated.

The anomalous Nernst material 151, as well as the anomalous Nernst material 11 of the first to third exemplary embodiments, only needs to be a ferromagnetic body having conductivity and include an element (second element) that significantly has the inverse spin-Hall effect and is spin-polarized. The anomalous Nernst material 151 includes, for example, an element (third element) for spin-polarizing the second element.

The spin-Seebeck material 152, as well as the spin-Seebeck material 14 of the third exemplary embodiment, only needs to be a material having the spin-Seebeck effect, such as a magnetic body.

Also in this exemplary embodiment, both the anomalous Nernst material 151 and the spin-Seebeck material 152 in the power generation structure 15 are magnetized in a predetermined direction (e.g., the x direction in FIG. 16) in the in-plane direction.

When a heat flow is caused to flow through such the thermoelectric conversion element 10C in a direction perpendicular to the magnetization direction (e.g., the z direction in FIG. 16), a spin current is generated in a direction of the heat flow in the spin-Seebeck material 152 of the power generation structure 15. The spin current enters the anomalous Nernst material 151, and a first electric field is generated in the in-plane direction (the y direction in FIG. 16) of the power generation structure 15 by the inverse spin-Hall effect of the anomalous Nernst material 151. In this exemplary embodiment, in addition to the first electric field, a second electric field is also generated in the same direction as that of the first electric field (an outer product direction of the magnetization direction and the heat flow direction) in the power generation structure 15 by the anomalous Nernst effect of the anomalous Nernst material 151. As a result, thermoelectromotive force obtained by adding the first electric field and the second electric field can be taken out from the terminals 12 attached to both the ends of the power generation structure 15.

Other points are the same as in the first to third exemplary embodiments.

Next, a method of manufacturing the thermoelectric conversion element 10C of this exemplary embodiment will be described with reference to FIG. 16. In this exemplary embodiment, the power generation structure 15 is first manufactured. Examples of a method thereof encompass a method of baking fine particles of the spin-Seebeck material 152 coated with the anomalous Nernst material 151 by sputtering, plating, or the like, and a method of baking fine particles of the spin-Seebeck material 152 and the anomalous Nernst material 151 as they are. Next, at least the pair of terminals 12 is attached to the prepared power generation structure 15.

When a direction (desired electric field direction) in which the terminals 12 of the thermoelectric conversion element 10C thus obtained are arranged is the y direction in FIG. 16, thermoelectromotive force can be taken out from the terminals 12 by applying a magnetic field to the thermoelectric conversion element 10C in the x direction and a temperature gradient thereto in the z direction. Note that the above manufacturing method is merely an example, and is not limited thereto.

As described above, according to this exemplary embodiment, it is possible to further increase output of the thermoelectric conversion element as in the third exemplary embodiment.

### EXAMPLES

### Example 1

As a first example, the thermoelectric conversion element 10A of FIG. 14 was prepared. The anomalous Nernst materials 11 used in the thermoelectric conversion element 10A of this example were M1 to M4 described above. A Si substrate was used as the substrate 13. Cu was used as a material of the terminals 12.

First, anomalous Nernst material films are deposited by sputtering on the Si substrates each of which has a thickness of 381 μm, a length of 2 mm in the x direction, and a length of 8 mm in the y direction. In this example, films of M1 to M4 described above were deposited as the anomalous Nernst material films. Specifically, each anomalous Nernst material layer was obtained by simultaneously sputtering a Co target and a Pt target under Ar and N₂ atmospheres. Note that the flow rate of N₂ gas during sputtering was set to 0 when the M1 film was deposited, and the flow rate of N₂ gas was changed when the M2 to M4 films were deposited.

The composition ratios of the obtained anomalous Nernst material layers (M1 to M4) are as described above. Each anomalous Nernst material layer had a thickness of 10 nm. Terminals (electrodes) were attached to each of the four anomalous Nernst material layers thus obtained so that a distance between the electrodes was 6 mm. In this way, four thermoelectric conversion elements were obtained. Hereinafter, by adding the used anomalous Nernst materials 11 to the head of the respective elements, the four thermoelectric conversion elements will be referred to as “M1 element”, “M2 element”, “M3 element”, and “M4 element”.

A magnetic field was applied to each of the obtained thermoelectric conversion elements in the x direction in FIG. 14 to magnetize the thermoelectric conversion element, and a temperature gradient was applied thereto in the z direction in FIG. 14 which is a direction perpendicular to magnetization. Then, a voltage between the terminals 12 was measured. The temperature gradient was applied by sandwiching the thermoelectric conversion element between Peltier elements. The magnetic field was applied by using an electromagnet. The thermoelectromotive force of FIG. 10 is a measurement result of the thermoelectric conversion element of this example. Specifically, the thermoelectromotive force of FIG. 10 is a value obtained when the temperature gradient of 1K is applied between an upper part of the anomalous Nernst material 11 and a lower part of the substrate 13.

Electrical resistances of the M1 to M4 elements at this time were 279.9Ω, 305.2Ω, 335.0Ω, and 397.7Ω as a result of measurement of the two terminals between 6 mm. P.F. was calculated on the basis of those resistance values and the value of the electromotive force. The P.F.s of the M1, M2, M3, and M4 elements were 3.2 pW/K², 3.5 pW/K², 4.0 pW/K², and 3.4 pW/K², respectively. Note that those values are values obtained by normalizing the sample size to 1 mm×1 mm. The thermal conductivity of the Si substrate was 148 W/(mK²).

Thermoelectromotive force could be generated in the y direction in each of the thermoelectric conversion element of this example. However, FIG. 10 shows that the larger the amount of N in CoPtN is, the greater the thermoelectromotive force caused by the anomalous Nernst effect becomes. Further, FIG. 11 shows that the higher the spin polarization of Pt atoms in CoPtN is, the greater the thermoelectromotive force caused by the anomalous Nernst effect becomes. Thus, this example demonstrated that the thermoelectric conversion efficiency is improved as the spin polarization of Pt atoms in the anomalous Nernst material is stronger, as predicted by the material development system 20. Further, by changing the flow rate of N₂ gas to adjust the amount of N in CoPtN, it is possible to obtain a more efficient spin thermoelement.

### Example 2

Example 1 shows that the more N is inserted into a thin film alloy of Co and Pt, the greater the thermoelectric efficiency caused by the anomalous Nernst effect becomes. Thus, it is expected that the thermoelectromotive force caused by the anomalous Nernst effect is also increased by inserting N into a bulk alloy of Co and Pt.

In this example, the thermoelectric conversion element 10 (bulk spin thermoelement) of FIG. 1 was prepared. CoPtN was used as the anomalous Nernst material 11 of the bulk spin thermoelement of this example.

In the bulk spin thermoelement of this example, the anomalous Nernst material 11 (structure) was first prepared by sintering Co fine particles and Pt fine particles by spark plasma sintering under a N₂ atmosphere. Then, the pair of terminals 12 was attached to both the ends of the prepared anomalous Nernst material 11.

Also in a case of the bulk spin thermoelement thus prepared, thermoelectromotive force can be generated in the y direction in FIG. 1 by applying a magnetic field in the x direction in FIG. 1 to magnetize the bulk spin thermoelement and applying a temperature gradient in the z direction in FIG. 1 which is a direction perpendicular to magnetization. Therefore, the thermoelectromotive force can be taken out from the terminals 12. In this example, as well as in the first example, by changing the flow rate of the N₂ gas to adjust the amount of N in CoPtN, a more efficient bulk spin thermoelement can be obtained.

### Example 3

Example 1 shows that the more N is inserted into a thin film alloy of Co and Pt, the greater the thermoelectric efficiency caused by the anomalous Nernst effect becomes. Therefore, further improvement in the thermoelectromotive force can be expected by incorporating the spin-Seebeck material into the anomalous Nernst material.

In this example, the thermoelectric conversion element 10C (hybrid structure spin thermoelement) of FIG. 16 was prepared. CoPtN was used as the anomalous Nernst material 151 in the power generation structure 15 of the hybrid structure spin thermoelement of this example. Bi:YIG was used as the spin-Seebeck material 152 in the power generation structure 15.

First, Bi:YIG fine particles were coated with a CoPtN film by sputtering. Specifically, Co and Pt were simultaneously sputtered under a N₂ atmosphere on a sample substrate on which the Bi:YIG fine particles were placed. Thereafter, the Bi:YIG fine particles coated with CoPtN were sintered in a vacuum by plasma sintering. Thus, the power generation structure 15, which is a hybrid structure of the anomalous Nernst material and the spin-Seebeck material, was prepared. Then, the pair of terminals 12 was attached to both ends of the prepared power generation structure 15.

Also in a case of the hybrid structure spin thermoelement thus prepared, thermoelectromotive force can be generated in the y direction in FIG. 16 by applying a magnetic field in the x direction in FIG. 16 to magnetize the hybrid structure spin thermoelement and applying a temperature gradient in the z direction in FIG. 16 which is a direction perpendicular to magnetization. Therefore, the thermoelectromotive force can be taken out from the terminals 12. At this time, the obtained thermoelectromotive force is the total of the electromotive force from the first electric field generated in the anomalous Nernst material 151 by the spin current generated from the spin-Seebeck material 152 of the power generation structure 15 and the electromotive force generated from the second electric field generated by the anomalous Nernst effect of the anomalous Nernst material 151 itself. In this example, as well as in the first example, by changing the flow rate of N₂ gas to adjust the amount of N in CoPtN, a more efficient hybrid structure spin thermoelement can be obtained.

The above exemplary embodiments can also be described as in the following supplementary notes.

(Supplementary note 1) A thermoelectric conversion element, including an anomalous Nernst material having the anomalous Nernst effect, in which: the anomalous Nernst material includes at least an element having the inverse spin-Hall effect; and the element having the inverse spin-Hall effect is spin-polarized.

(Supplementary note 2) The thermoelectric conversion element according to Supplementary note 1, in which a normalized voltage obtained by the anomalous Nernst effect of the anomalous Nernst material is 21 μV/K or more.

(Supplementary note 3) The thermoelectric conversion element according to Supplementary note 1 or 2, in which the element having the inverse spin-Hall effect has a spin polarization rate of 0.15 or more.

(Supplementary note 4) The thermoelectric conversion element according to any one of Supplementary notes 1 to 3, in which the element having the inverse spin-Hall effect is an element having an electron in a 4d or more orbital.

(Supplementary note 5) The thermoelectric conversion element according to Supplementary note 4, in which the element having the inverse spin-Hall effect is Pt.

(Supplementary note 6) The thermoelectric conversion element according to any one of Supplementary notes 1 to 5, in which the anomalous Nernst material is a multi-element system including three or more elements and includes at least a first element belonging to a magnetic metal, a second element that is the element having the inverse spin-Hall effect, and a third element that spin-polarizes the second element or improves a spin polarization rate of the second element.

(Supplementary note 7) The thermoelectric conversion element according to Supplementary note 6, in which the third element is any one of groups 1 to 2 elements and groups 8 to 12 elements or any one of second-period elements.

(Supplementary note 8) The thermoelectric conversion element according to Supplementary note 6 or 7, in which a composition ratio of the second element to the first element in the anomalous Nernst material is 0.7 or more but 1.3 or less.

(Supplementary note 9) The thermoelectric conversion element according to any one of

Supplementary notes 6 to 8, in which a ratio of atoms corresponding to the third element to the total number of atoms in the anomalous Nernst material is 0.02 or more.

(Supplementary note 10) The thermoelectric conversion element according to any one of Supplementary notes 1 to 9, in which the anomalous Nernst material is Coₙ₁Ptₙ₂N₁₋ₙ₁₋ₙ₂ (where 0<n1<1, 0<n2<1, 0<n1+n2<1).

(Supplementary note 11) The thermoelectric conversion element according to any one of Supplementary notes 1 to 10, in which: the anomalous Nernst material is formed as a structure having a predetermined thickness; and at least a pair of terminals is provided on the structure of the anomalous Nernst material.

(Supplementary note 12) The thermoelectric conversion element according to any one of Supplementary notes 1 to 11, further including a substrate, in which the anomalous Nernst material is formed on the substrate.

(Supplementary note 13) The thermoelectric conversion element according to any one of Supplementary notes 1 to 11, further including: a substrate; and a spin-Seebeck material having the spin-Seebeck effect, in which the anomalous Nernst material is formed on the spin-Seebeck material formed on the substrate.

(Supplementary Note 14) The thermoelectric conversion element according to any one of Supplementary notes 1 to 10, further including a power generation structure that is a structure in which the anomalous Nernst material and a spin-Seebeck material having the spin-Seebeck effect are mixed, in which: the power generation structure has a predetermined thickness; and at least a pair of terminals is provided on the power generation structure.

The present invention has been described with reference to the above exemplary embodiments and examples. However, the present invention is not limited to the above exemplary embodiments and examples. Various changes that can be understood by those skilled in the art can be made in the configuration and details of the present invention within the scope of the present invention.

This application claims the benefit of priority based on Japanese patent application No. 2017-187730, filed on Sep. 28, 2017, the disclosure of which is incorporated herein in its entirety by reference.

### INDUSTRIAL APPLICABILITY

The present invention is applicable to various uses for the purpose of obtaining electric power from heat.

### REFERENCE SIGNS LIST

10, 10A, 10B, 10C Thermoelectric conversion element
11, 151 Anomalous Nernst material
12 Terminal
13 Substrate
14, 152 Spin-Seebeck material
15 Power generation structure
20 Material development system
21 Information processing device
22 Storage device
23 Input device
24 Display device
25 Communication device
211 Crystal structure determination means
212 Calculation data conversion means
213 Analysis means

1. A thermoelectric conversion element, comprising
an anomalous Nernst material having the anomalous Nernst effect, wherein:
the anomalous Nernst material includes at least an element having the inverse spin-Hall effect; and
the element having the inverse spin-Hall effect is spin-polarized.

2. The thermoelectric conversion element according to claim 1, wherein a normalized voltage obtained by the anomalous Nernst effect of the anomalous Nernst material is 21 μV/K or more.

3. The thermoelectric conversion element according to claim 1, wherein
the element having the inverse spin-Hall effect has a spin polarization rate of 0.15 or more.

4. The thermoelectric conversion element according to claim 1, wherein
the element having the inverse spin-Hall effect is an element having an electron in a 4d or more orbital.

5. The thermoelectric conversion element according to claim 4, wherein
the element having the inverse spin-Hall effect is Pt.

6. The thermoelectric conversion element according to claim 1, wherein
the anomalous Nernst material is a multi-element system including three or more elements and includes at least a first element belonging to a magnetic metal, a second element that is the element having the inverse spin-Hall effect, and a third element that spin-polarizes the second element or improves a spin polarization rate of the second element.

7. The thermoelectric conversion element according to claim 6, wherein
the third element is any one of groups 1 to 2 elements and groups 8 to 12 elements or any one of second-period elements.

8. The thermoelectric conversion element according to claim 6, wherein
a composition ratio of the second element to the first element in the anomalous Nernst material is 0.7 or more but 1.3 or less.

9. The thermoelectric conversion element according to claim 6, wherein
a ratio of atoms corresponding to the third element to the total number of atoms in the anomalous Nernst material is 0.02 or more.

10. The thermoelectric conversion element according to claim 1, wherein
the anomalous Nernst material is Coₙ₁Ptₙ₂N₁₋ₙ₁₋ₙ₂ (where 0<n1<1, 0<n2<1, 0<n1+n2<1).

11. The thermoelectric conversion element according to claim 1, wherein:
the anomalous Nernst material is formed as a structure having a predetermined thickness; and
at least a pair of terminals is provided on the structure of the anomalous Nernst material.

12. The thermoelectric conversion element according to claim 1, further comprising
a substrate, wherein
the anomalous Nernst material is formed on the substrate.

13. The thermoelectric conversion element according to claim 1, further comprising:
a substrate; and
a spin-Seebeck material having the spin-Seebeck effect, wherein
the anomalous Nernst material is formed on the spin-Seebeck material formed on the substrate.

14. The thermoelectric conversion element according to claim 1, further comprising
a power generation structure that is a structure in which the anomalous Nernst material and a spin-Seebeck material having the spin-Seebeck effect are mixed, wherein:
the power generation structure has a predetermined thickness; and
at least a pair of terminals is provided on the power generation structure.
